(19) United States
(12) Patent Application Publication
(10) Pub. No.: US 2024/0206348 A1
(43) Pub. Date: Jun. 20, 2024

(54) PROBABILISTIC AND DETERMINISTIC LOGIC DEVICES WITH REDUCED SYMMETRY MATERIALS

(71) Applicant: Intel Corporation, Santa Clara, CA (US)

(72) Inventors: Punyashloka Debashis, Hillsboro, OR (US); Ian Alexander Young, Olympia, WA (US); Dmitri Evgenievich Nikonov, Beaverton, OR (US); Chia-Ching Lin, Portland, OR (US); Hai Li, Portland, OR (US)

(73) Assignee: Intel Corporation, Santa Clara, CA (US)

(21) Appl. No.: 18/083,493

(22) Filed: Dec. 17, 2022

(51) Int. Cl. H10N 52/85; G11C 11/16; H03K 19/20; H10B 61/00; H10N 50/10; H10N 50/85

(52) U.S. Cl. CPC H10N 52/85; G11C 11/161; G11C 11/1673; G11C 11/1675; H03K 19/20; H10B 61/22; H10N 50/10; H10N 50/85

(57) ABSTRACT

In embodiments herein, probabilistic and deterministic logic devices include reduced symmetry materials, such as two-dimensional (2D) transition metal dichalcogenide (TMD) materials (e.g., NbSe₂ or MoTe₂).

### BACKGROUND

Current probabilistic logic devices utilize magnetic tunnel junctions (MTJS) to read the state of a thermally unstable nanomagnet. However, these MTJS can produce unwanted stray magnetic field and spin transfer torque effects on the nanomagnet and can affect the probability of the device's output. Further, current magnetoelectric spin orbit (MESO) logic devices may use heavy metals (e.g., Ta or Pt) for spin-to-charge conversions within the device, but these metals do not produce a large output voltage due to their low spin diffusion length and moderate spin Hall angle.

### BRIEF DESCRIPTION OF THE DRAWINGS

FIGS. 1A-1B illustrate example magnetic tunnel junction (MTJ)-based devices.

FIGS. 2A-2C illustrate an example probabilistic logic device that incorporates a reduced symmetry material in accordance with embodiments herein.

FIG. 3 illustrates an example magnetoelectric spin orbit (MESO) logic device that incorporates a reduced symmetry material in accordance with embodiments herein.

FIG. 4 is a top view of a wafer and dies that may be included in a microelectronic assembly, in accordance with any of the embodiments disclosed herein.

FIG. 5 is a cross-sectional side view of an integrated circuit device that may include any of the embodiments disclosed herein.

FIG. 6 is a cross-sectional side view of an integrated circuit device assembly that may include any of the embodiments disclosed herein.

FIG. 7 is a block diagram of an example electrical device that may include any of the embodiments disclosed herein.

### DETAILED DESCRIPTION

Embodiments herein utilize a new class of reduced symmetry (also sometimes referred to as low symmetry) two dimensional (2D) materials in probabilistic and deterministic logic devices. For example, some embodiments may implement such materials in a probabilistic logic device whose output voltage fluctuates with a probability tuned by a current through these materials. These reduced symmetry materials can allow for a simpler device design with no unwanted magnetic fields and/or can allow for currents that can bias the output probability distribution. As another example, some embodiments may implement such materials in a deterministic magnetoelectric spin orbit (MESO) logic device (e.g., in an output module of such a device), which may provide an improved spin-to-charge conversion module for generating larger output voltages.

Example reduced symmetry materials may include 2D transition metal dichalcogenide (TMD) materials, such as, for example, NbSe₂ or MoTe₂. Other 2D materials may also be utilized where reduced symmetry in the crystal allows for spin-charge interconversion not requiring to satisfy a right triplet. As used herein, a reduced symmetry material may refer to a material that does not have full mirror symmetry in all of its axes of its crystal structure. That is, the material does not have mirror symmetry in at least one axis of its crystal axes. Reduced symmetry materials that may be implemented herein may include one material (e.g., the TMD materials described previously) or can be a heterostructure comprising two reduced symmetry materials, one full symmetry material (e.g., graphene) and one reduced symmetry material in a stack, or two full symmetry materials that, when stacked, lead to a reduction in symmetry.

Probabilistic devices that incorporate these reduced symmetry materials may realize one or more advantages over current device designs. As one example, probabilistic devices utilizing these materials don't need the spin current density, charge current density, and spin polarization to be orthogonal as with current spin orbital materials. In addition, devices according to the present disclosure may include a single low barrier ferromagnet instead of an MTJ, which makes the stack design simpler over current devices. As another example, devices according to the present disclosure may eliminate unwanted stray fields and/or spin-transfer-torque effects from the MTJ reference layer. Furthermore, deterministic logic devices incorporating reduced symmetry materials may realize one or more advantages over current device designs, e.g., they may have a higher spin diffusion length, resulting in higher output voltages as compared with traditional heavy metal spin orbit (SO) materials.

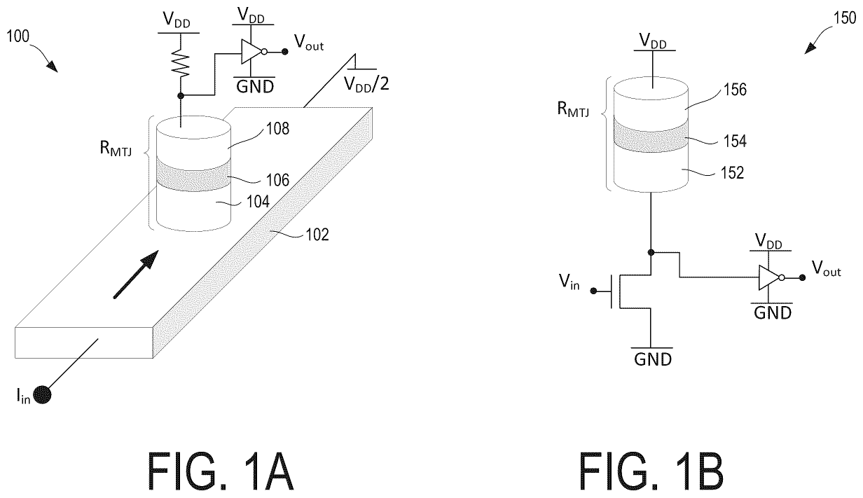

FIGS. 1A-1B illustrate example magnetic tunnel junction (MTJ)-based devices 100, 150. Referring first to FIG. 1A, the example device 100 includes a spin orbit torque (SOT) bottom electrode 102 with a thermally unstable nanomagnet on the SOT electrode 102. The nanomagnet includes ferromagnetic (FM) layers 104, 108 with an insulating material layer 106 between the FM layers 104, 108 that may act as a tunnel barrier. The insulating material layer 106 may be formed from or comprise a metal oxide, and the FM layers 104, 108 may comprise any suitable conducting ferromagnetic material, such as cobalt, iron, nickel, or an alloy of conducting ferromagnetic material, such as CoFe, CoFeB, and NiFe, as well as ferromagnetic oxides, such as Sr₂FeMoO₆ (SFMO), Sr₂CrReO₆ (SCRO), La_{0.7}Sr_{0.3}MnO₃ (LSMO), and Fe₃O₄. Turning to FIG. 1B, the example device 150 likewise includes nanomagnet includes ferromagnetic (FM) layers 152, 156 with an insulating material 154 between the ferromagnetic layers 152, 156. The bottom FM layers 104, 152 of the nanomagnets may be referred to as thermally unstable free layers, while the top FM layers 108, 156 of the nanomagnets may be referred to as reference layers (due to their relative stability).

The nanomagnets in the devices 100, 150 create an electrical resistance (RMTJ) that is based on the magnetic tunnel junction (MTJ) created by the insulating layer between the FM layers. Fluctuations in the nanomagnets are converted to a fluctuating output voltage (Vout) through the MTJS in the devices. The MTJ resistance changes as function of the relative orientation of the thermally unstable free layers and the stable reference layer. However, in each of these designs, the reference layers (108, 156) produce an unwanted stray magnetic field on the free layers (104, 152). In addition, a read current passing through the MTJ imparts an unwanted spin transfer torque on the free layers. Both of these effects can bias the random fluctuations of the free layer nanomagnet and hence adversely affect the probability distribution of the output voltages provided. This issue is avoided in embodiments herein, as the devices proposed herein do not contain a second magnetic reference layer like the devices 100, 150.

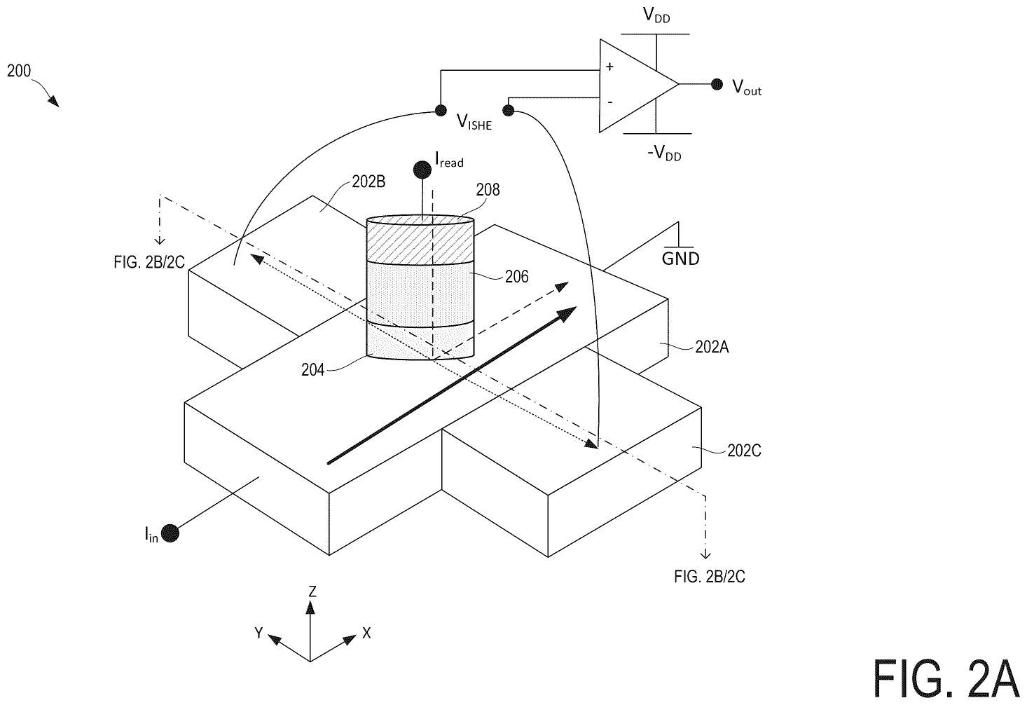

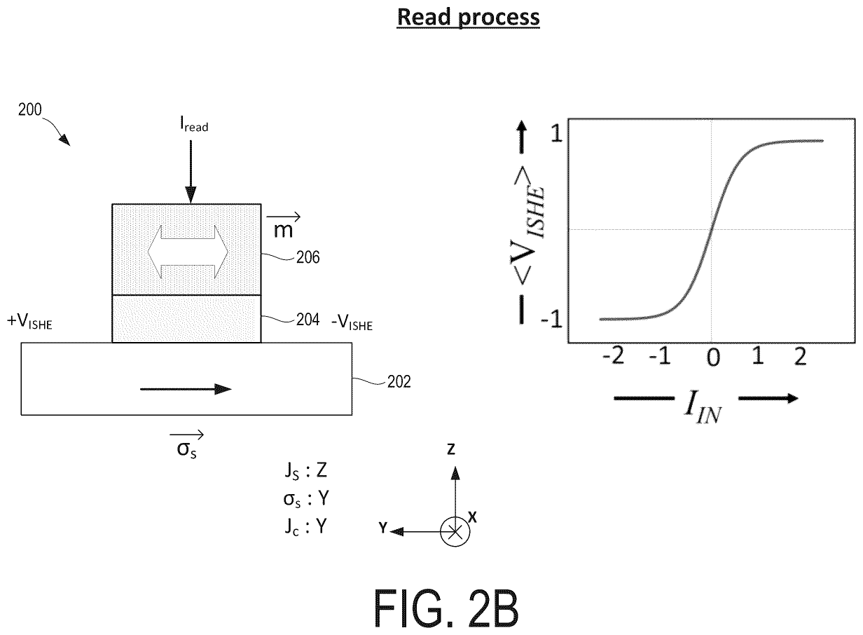

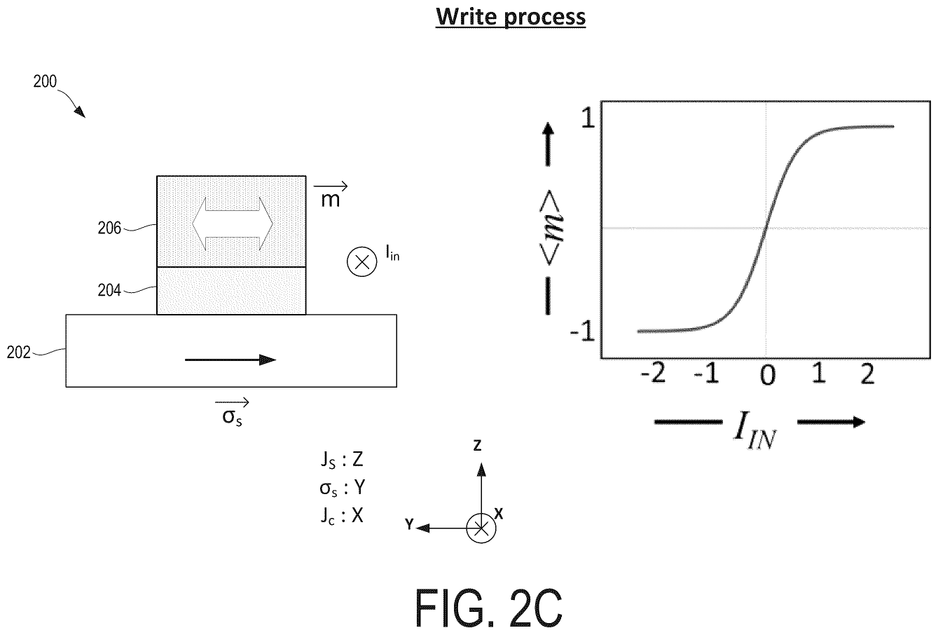

FIGS. 2A-2C illustrate an example probabilistic logic device 200 that incorporates a reduced symmetry material in accordance with embodiments herein. In particular, FIG. 2A illustrates a perspective view of the device 200, while FIGS. 2B-2C illustrate cross-sectional views of the device 200 through the center of the device (as shown in FIG. 2A). The device 200 includes a spin orbit (SO) layer 202 that is formed from or includes a reduced symmetry 2D material as described herein. The SO layer 202 may be formed in a Hall cross structure as shown with wing portions 202B, 202C of the SO layer 202 extending from a main portion 202A of the SO layer 202. The device 200 also includes a nanomagnet on the SO layer 202, with the nanomagnet being in the middle of the Hall cross formation of the SO layer, i.e., in alignment with the wing portions 202B, 202C. The nanomagnet includes a single FM material layer 206 on an insulating material layer 204. The FM material 206 may be a thermally unstable nanomagnet. The insulating material layer 204 between the FM layer 206 and the SO layer 202 may act as a tunnel barrier for conductance matching between the FM material of the layer 206 and the semi-metallic reduced symmetry material (e.g., TMD) of the layer 202. The insulating material layer 204 may be formed from or comprise a metal oxide (e.g., magnesium oxide (MgO), aluminum oxide (Al₂O₃), or copper oxide (CuOx)), a 2D material insulator (e.g., hexagonal Boron Nitride (hBN)), or an antiferromagnetic oxide (e.g., NiO), and may be approximately 0.3-5 nm in thickness. The FM material layer 206 may be formed from or comprise any suitable conducting ferromagnetic material, such as, for example, cobalt, iron, nickel, or an alloy of conducting ferromagnetic material, such as CoFe, CoFeB, and NiFe, as well as ferromagnetic metallic oxides, such as Sr₂FeMoO₆ (SFMO), Sr₂CrReO₆ (SCRO), La_{0.7}Sr_{0.3}MnO₃ (LSMO), or Fe₃O₄. The thickness of the FM material layer may be approximately 1.5-50 nm (and may be limited by exchange coupling and exchange bias with the magnetoelectric layer, that scales inversely with FM material thickness). The device 200 further includes a conductive electrode 208 on the FM material layer 206.

In operation, a charge current (I_{read}) is passed through the nanomagnet into the SO layer 202 with the reduced symmetry material, with the current path being shown in FIG. 2A by the dashed arrow lines. This charge current is polarized by the nanomagnet FM layer 206 and is injected into the TMD channel as a spin current. Then, an un-conventional spin-to-charge conversion occurs in the SO layer with the reduced symmetry material, resulting in a charge voltage shown as V_{ISHE} that changes sign as the nanomagnet direction fluctuates in the FM layer 206. This is shown by the dotted arrow line in the transverse direction in FIG. 2A.

Read and write processes for the device 200 are shown in FIGS. 2B-2C, respectively. As shown in the Y-Z plane side view image of the device 200 in FIG. 2B, during a read process, the injected spin current (J_{S}), spin polarization (σ_{S}) and the output charge current (J_{C}) are in the Z, Y, and Y directions, respectively, and thus, do not form a right triplet. This behavior would not be supported in a conventional spin orbit material if used in the SO layer 202. However, when a reduced symmetry material (e.g., TMDs) are used in the SO layer 202, such behavior is allowed, and hence, the readout of the nanomagnet state is enabled.

Referring to the write process shown in FIG. 2C, a second charge current Iᵢₙ is applied to the longitudinal arm of the SO layer 202 (shown by bold arrow in FIG. 2A). This charge current results in a spin current that produces a spin torque on the nanomagnet FM layer 206, biasing its fluctuations and changing the output probability of the device 200. This charge-to-spin conversion does satisfy the right triplet as shown in FIG. 2C (with the injected spin current (J_{S}), spin polarization (σ_{S}) and the input charge current (J_{C}) being in the Z, Y, and X directions, respectively), which is also allowed by the reduced symmetry material of the SO layer 202.

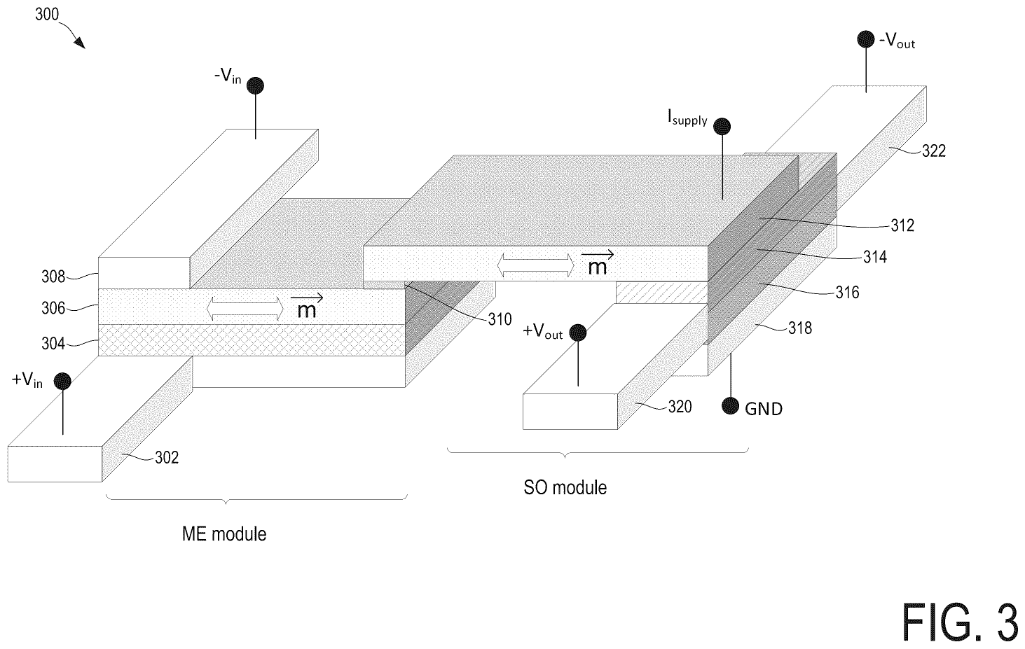

FIG. 3 illustrates an example magnetoelectric spin orbit (MESO) logic device 300 that incorporates a reduced symmetry material in accordance with embodiments herein. In particular, the reduced symmetry material is incorporated within the spin orbital coupling layer 316 of the device 300, which can allow for larger output voltages from the device 300 as described above. The example device 300 includes a magnetoelectric (ME) module on its input side and a spin orbit (SO) module on its output side, with the ME module and SO module being magnetically coupled together.

The ME module may be referred to as a ME capacitor region, and includes two non-magnetic electrical conductors 302 (which provides a positive input bias or voltage, +Vin) and 308 (which provides a negative input bias or voltage, −Vin). Between the conductors 302, 308 are a magnetoelectric (ME) material 304 and a first ferromagnetic (FM) material layer 306. The ME capacitor region may be charged and discharged by virtue of the bias applied between +Vin and −Vin. A charging and discharging of the ME capacitor region corresponds to a change in the information state of the ME capacitor.

The SO module includes SO a second FM material layer 312 that is on a spin orbit coupling stack (SOC stack) that includes a spin coherent layer 314 and spin orbital coupling layer 316. The spin orbital coupling layer 316 is in contact with a non-magnetic electrical conductor 320. The SO module provides a structure that, when subjected to a supply current (I_{supply}, e.g., supplied by way of a transistor) first converts the supply current to a spin current by virtue of the current contacting the second FM material layer 312, and thereafter converts the spin current to an output supply current flowing horizontally in the positive or negative x direction depending on the magnetization direction of second FM material layer 312. The output current of the device generates an output voltage between the electrodes 320, 322 as shown. In embodiments herein, the SO coupling layer 316 may include a reduced symmetry material (e.g., a reduced symmetry 2D TMD material) as described herein.

The ME capacitor region is coupled to the SO module by via a dielectric coupling layer 310. The coupling layer is to electrically insulate the ME module from the SO module while providing magnetic coupling between the first FM material layer 306 and the second FM layer 312. The coupling layer may be formed from or comprise Fe₃O₄, CoFe₂O₄, EuO, Fe₂O₃, Co₂O₃, CO₂FeO₄, Ni₂FeO₄, (Ni,Co)₁₊₂ₓTi1−xO₃, yttrium iron garnet (YIG)=Y₃Fe₅O₁₂, (MgAl_{0.5}Fe_{1.5}O₄, MAFO), or (NiAFO, NiAl Fe₂₋ₓO₄).

The ME material layer 304 may comprise any suitable magnetoelectric and/or multiferroic material (e.g., a multiferroic oxide), such as a material that includes, for example, bismuth (Bi), iron (Fe), oxygen (O), lanthanum (La), chromium (Cr), and/or boron (B), such as bismuth iron oxide (BiFeO₃ or BFO), doped bismuth iron oxide (e.g., BiFeO₃ doped with lanthanum, ((Bi₁₋ₓLaₓ)FeO₃ or LBFO), chromium oxide (Cr₂O₃), and doped chromium oxide (e.g., Cr₂O₃doped with boron). The FM layers 306, 312 may comprise any suitable conducting ferromagnetic material, such as cobalt, iron, nickel, or an alloy of conducting ferromagnetic material, such as CoFe, CoFeB, and NiFe, as well as ferromagnetic oxides, such as Sr₂FeMoO₆ (SFMO), Sr₂CrReO₆ (SCRO), La_{0.7}Sr_{0.3}MnO₃ (LSMO), and Fe₃O₄

In operation, application of a voltage to the ME module switches a ferroelectric polarization within the module, inducing a 180-degree switching of the magnetization with the ME layer 304. This in turn switches the magnetization of the adjacent in-plane magnetic anisotropy (IMA) ferromagnet (FM) in layer 306. The second IMA FM in layer 312 of the SO module and follows the switching of the first FM. The direction of its magnetization is then read out through spin-to-charge conversion using an adjacent material with a strong spin-orbit (SO) coupling that generates an output charge voltage depending upon the orientation of the second IMA FM. The product of spin Hall angle and the spin diffusion length (θ_{SH}*λ_{S}) of the SO material may determine the output voltage, and the reduced symmetry materials (e.g., reduced symmetry 2D TMD materials) proposed herein have a larger (θ_{SH}*λ_{S}) compared to heavy metals (e.g., Ta or Pt) used in current MESO devices and hence, would produce a large Vout signal.

Furthermore, efficient injection of spin current from the FM material layer into the SO material of the output SO module is critical to achieving a large output voltage. This injection efficiency depends on the conductance match between the FM and the SO materials. Reduced symmetry materials, such as semi-metallic reduced symmetry 2D TMD materials, promise to have better conductance matching with the typically metallic FM materials used in MESO devices such as 300.

The probabilistic logic devices and/or deterministic logic devices described herein can be implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

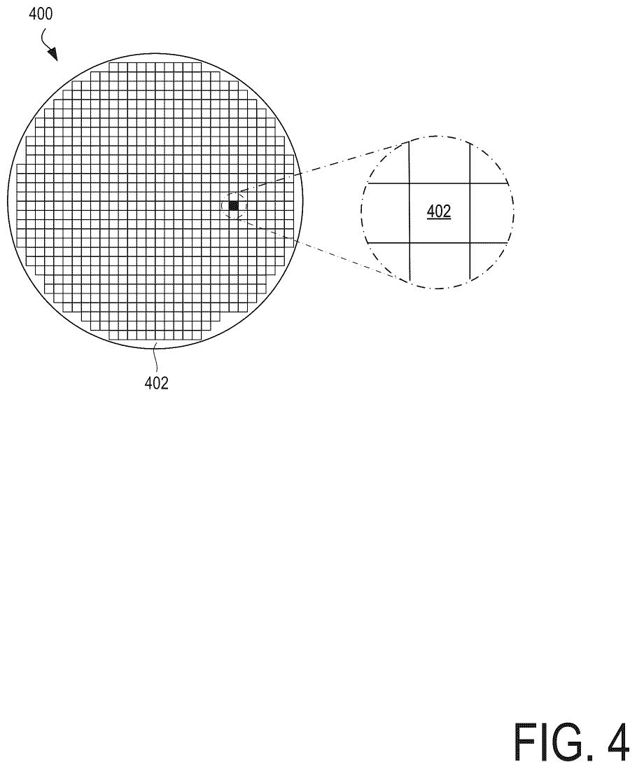

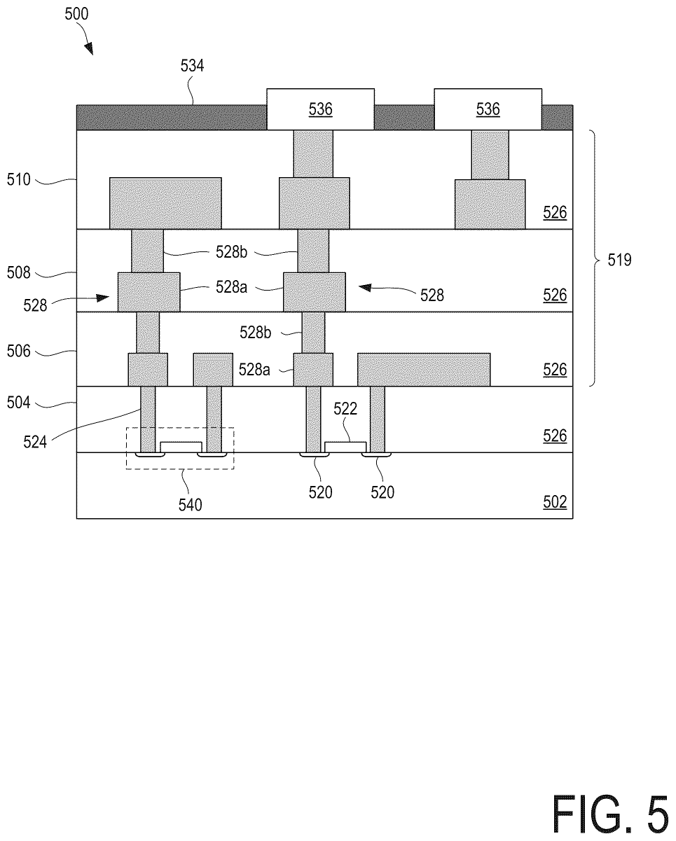

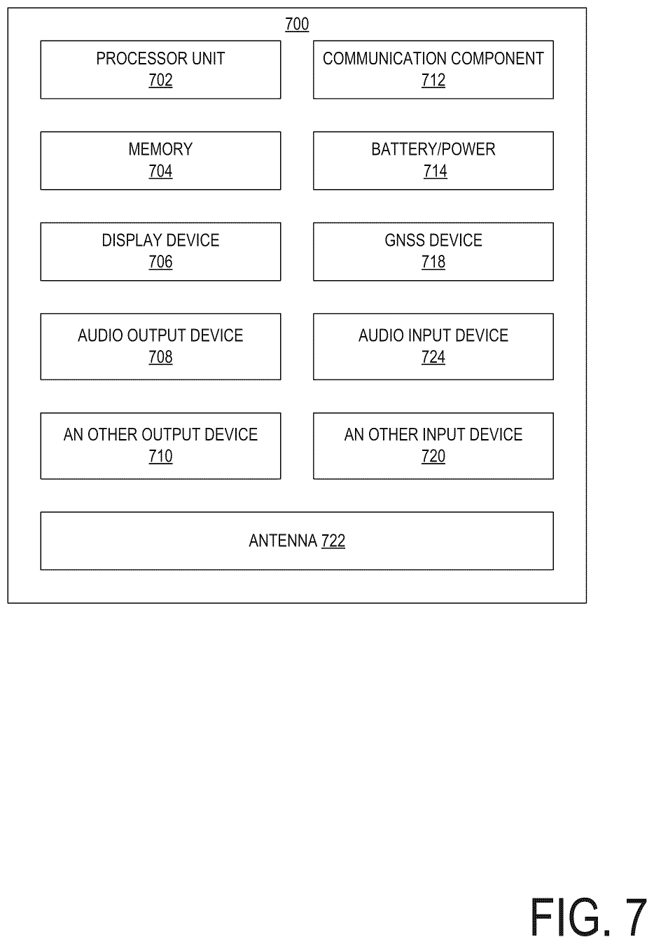

FIG. 4 is a top view of a wafer 400 and dies 402 that may incorporate any of the embodiments disclosed herein. The wafer 400 may be composed of semiconductor material and may include one or more dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The die 402 may include one or more transistors (e.g., some of the transistors 540 of FIG. 5, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processor unit (e.g., the processor unit 702 of FIG. 7) or other logic that is configured to store information in the memory devices or execute instructions stored in the memory array.

FIG. 5 is a cross-sectional side view of an integrated circuit device 500 that may be included in any of the embodiments disclosed herein. One or more of the integrated circuit devices 500 may be included in one or more dies 402 (FIG. 4). The integrated circuit device 500 may be formed on a die substrate 502 (e.g., the wafer 400 of FIG. 4) and may be included in a die (e.g., the die 402 of FIG. 4). The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit device 500 may be used. The die substrate 502 may be part of a singulated die (e.g., the dies 402 of FIG. 4) or a wafer (e.g., the wafer 400 of FIG. 4).

The integrated circuit device 500 may include one or more device layers 504 disposed on the die substrate 502. The device layer 504 may include features of one or more transistors 540 (e.g., metal oxide semiconductor field-effect transistors (MOSFETs)) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 5 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 5, a transistor 540 may include a gate 522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may consist of a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit device 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. Although a particular number of interconnect layers 506-510 is depicted in FIG. 5, embodiments of the present disclosure include integrated circuit devices having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 5. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 5. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the lines 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit device 500 (i.e., farther away from the device layer 504) may be thicker that the interconnect layers that are lower in the metallization stack 519, with lines 528a and vias 528b in the higher interconnect layers being thicker than those in the lower interconnect layers.

The integrated circuit device 500 may include a solder resist material 534 (e.g., polyimide or similar material) and one or more conductive contacts 536 formed on the interconnect layers 506-510. In FIG. 5, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit device 500 with another component (e.g., a printed circuit board). The integrated circuit device 500 may include additional or alternate structures to route the electrical signals from the interconnect layers 506-510; for example, the conductive contacts 536 may include other analogous features (e.g., posts) that route the electrical signals to external components.

In some embodiments in which the integrated circuit device 500 is a double-sided die, the integrated circuit device 500 may include another metallization stack (not shown) on the opposite side of the device layer(s) 504. This metallization stack may include multiple interconnect layers as discussed above with reference to the interconnect layers 506-510, to provide conductive pathways (e.g., including conductive lines and vias) between the device layer(s) 504 and additional conductive contacts (not shown) on the opposite side of the integrated circuit device 500 from the conductive contacts 536.

In other embodiments in which the integrated circuit device 500 is a double-sided die, the integrated circuit device 500 may include one or more through silicon vias (TSVs) through the die substrate 502; these TSVs may make contact with the device layer(s) 504, and may provide conductive pathways between the device layer(s) 504 and additional conductive contacts (not shown) on the opposite side of the integrated circuit device 500 from the conductive contacts 536. In some embodiments, TSVs extending through the substrate can be used for routing power and ground signals from conductive contacts on the opposite side of the integrated circuit device 500 from the conductive contacts 536 to the transistors 540 and any other components integrated into the die 500, and the metallization stack 519 can be used to route I/O signals from the conductive contacts 536 to transistors 540 and any other components integrated into the die 500.

Multiple integrated circuit devices 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

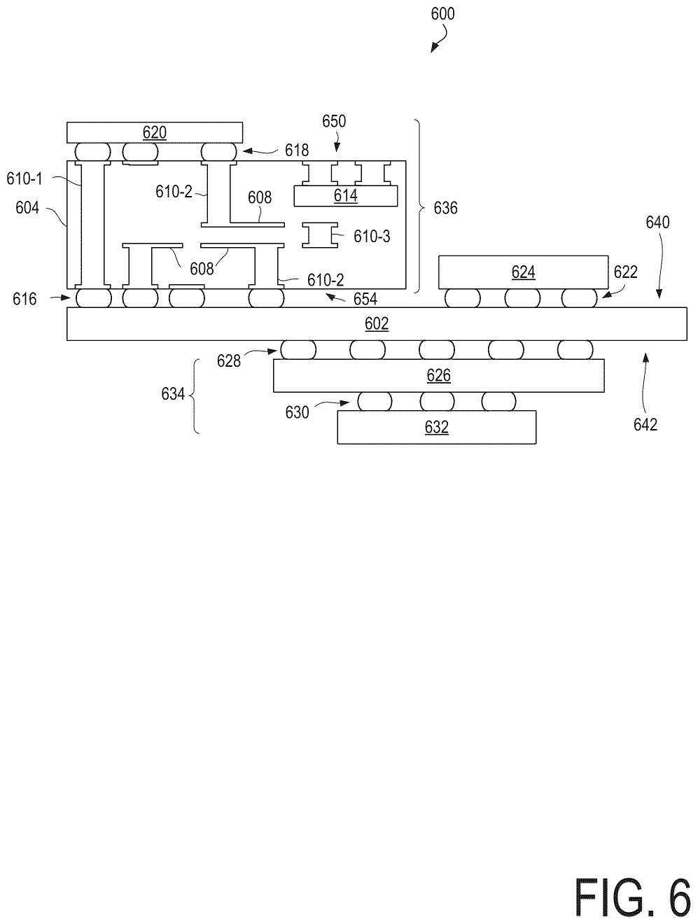

FIG. 6 is a cross-sectional side view of an integrated circuit device assembly 600 that may include any of the embodiments disclosed herein. The integrated circuit device assembly 600 includes a number of components disposed on a circuit board 602 (which may be a motherboard, system board, mainboard, etc.). The integrated circuit device assembly 600 includes components disposed on a first face 640 of the circuit board 602 and an opposing second face 642 of the circuit board 602; generally, components may be disposed on one or both faces 640 and 642.

In some embodiments, the circuit board 602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate. The integrated circuit device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 636 may include an integrated circuit component 620 coupled to an interposer 604 by coupling components 618. The coupling components 618 may take any suitable form for the application, such as the forms discussed above with reference to the coupling components 616. Although a single integrated circuit component 620 is shown in FIG. 6, multiple integrated circuit components may be coupled to the interposer 604; indeed, additional interposers may be coupled to the interposer 604. The interposer 604 may provide an intervening substrate used to bridge the circuit board 602 and the integrated circuit component 620.

The integrated circuit component 620 may be a packaged or unpacked integrated circuit product that includes one or more integrated circuit dies (e.g., the die 402 of FIG. 4, the integrated circuit device 500 of FIG. 5) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 620, a single monolithic integrated circuit die comprises solder bumps attached to contacts on the die. The solder bumps allow the die to be directly attached to the interposer 604. The integrated circuit component 620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 620 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 620 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 604 may spread connections to a wider pitch or reroute a connection to a different connection. For example, the interposer 604 may couple the integrated circuit component 620 to a set of ball grid array (BGA) conductive contacts of the coupling components 616 for coupling to the circuit board 602. In the embodiment illustrated in FIG. 6, the integrated circuit component 620 and the circuit board 602 are attached to opposing sides of the interposer 604; in other embodiments, the integrated circuit component 620 and the circuit board 602 may be attached to a same side of the interposer 604. In some embodiments, three or more components may be interconnected by way of the interposer 604.

In some embodiments, the interposer 604 may be formed as a PCB, including multiple metal layers separated from one another by layers of dielectric material and interconnected by electrically conductive vias. In some embodiments, the interposer 604 may be formed of an epoxy resin, a fiberglass-reinforced epoxy resin, an epoxy resin with inorganic fillers, a ceramic material, or a polymer material such as polyimide. In some embodiments, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through hole vias 610-1 (that extend from a first face 650 of the interposer 604 to a second face 654 of the interposer 604), blind vias 610-2 (that extend from the first or second faces 650 or 654 of the interposer 604 to an internal metal layer), and buried vias 610-3 (that connect internal metal layers).

In some embodiments, the interposer 604 can comprise a silicon interposer. Through silicon vias (TSV) extending through the silicon interposer can connect connections on a first face of a silicon interposer to an opposing second face of the silicon interposer. In some embodiments, an interposer 604 comprising a silicon interposer can further comprise one or more routing layers to route connections on a first face of the interposer 604 to an opposing second face of the interposer 604.

The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art. In embodiments where the interposer is a non-printed circuit board

The integrated circuit device assembly 600 may include an integrated circuit component 624 coupled to the first face 640 of the circuit board 602 by coupling components 622. The coupling components 622 may take the form of any of the embodiments discussed above with reference to the coupling components 616, and the integrated circuit component 624 may take the form of any of the embodiments discussed above with reference to the integrated circuit component 620.

The integrated circuit device assembly 600 illustrated in FIG. 6 includes a package-on-package structure 634 coupled to the second face 642 of the circuit board 602 by coupling components 628. The package-on-package structure 634 may include an integrated circuit component 626 and an integrated circuit component 632 coupled together by coupling components 630 such that the integrated circuit component 626 is disposed between the circuit board 602 and the integrated circuit component 632. The coupling components 628 and 630 may take the form of any of the embodiments of the coupling components 616 discussed above, and the integrated circuit components 626 and 632 may take the form of any of the embodiments of the integrated circuit component 620 discussed above. The package-on-package structure 634 may be configured in accordance with any of the package-on-package structures known in the art.

FIG. 7 is a block diagram of an example electrical device 700 that may include one or more of the embodiments disclosed herein. For example, any suitable ones of the components of the electrical device 700 may include one or more of the integrated circuit device assemblies 600, integrated circuit components 620, integrated circuit devices 500, or integrated circuit dies 402 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include an other output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a probabilistic logic device comprising: a spin orbit (SO) layer comprising a reduced symmetry material; an insulating layer on the SO layer; a ferromagnetic (FM) material layer on the insulating layer; and a conductive electrode on the FM material layer.

Example 2 includes the subject matter of Example 1, wherein the reduced symmetry material comprises a two-dimensional (2D) transition metal dichalcogenide (TMD) material.

Example 3 includes the subject matter of Example 2, wherein the 2D TMD material comprises at least one of Niobium, Selenium, Molybdenum, and Tellurium.

Example 4 includes the subject matter of any one of Examples 1-3, wherein the SO layer defines a Hall cross structure, and the insulating layer and FM layer are formed in a middle portion of the Hall cross structure.

Example 5 includes the subject matter of any one of Examples 1-4, wherein the SO layer comprises a heterostructure comprising a first reduced symmetry material and a second reduced symmetry material.

Example 6 includes the subject matter of any one of Examples 1-4, wherein the SO layer comprises a heterostructure comprising the reduced symmetry material and a full symmetry material.

Example 7 includes the subject matter of any one of Examples 1-6, wherein the insulating layer comprises at least one of Magnesium, Aluminum, and Oxygen.

Example 8 includes the subject matter of any one of Examples 1-7, wherein the FM material layer comprises at least one of Cobalt, Iron, and Nickel.

Example 9 is an integrated circuit device comprising a plurality of probabilistic logic devices, at least one probabilistic logic device according to one of Examples 1-8.

Example 10 is a deterministic logic device comprising: a magnetoelectric (ME) region comprising: an ME material layer; and a first ferromagnetic (FM) material layer on the ME material layer; a spin orbit (SO) region comprising: a spin orbital coupling layer comprising a reduced symmetry material; a spin coherent layer on the spin orbital coupling layer; a second FM material layer on the spin coherent layer; wherein the ME region and the SO region are magnetically coupled via the first FM material and the second FM material.

Example 11 includes the subject matter of Example 10, wherein the reduced symmetry material comprises a two-dimensional (2D) transition metal dichalcogenide (TMD) material.

Example 12 includes the subject matter of Example 11, wherein the 2D TMD material comprises at least one of Niobium, Selenium, Molybdenum, and Tellurium.

Example 13 includes the subject matter of any one of Examples 10-12, wherein the spin orbital coupling layer comprises a heterostructure comprising a first reduced symmetry material and a second reduced symmetry material.

Example 14 includes the subject matter of any one of Examples 10-12, wherein the spin orbital coupling layer comprises a heterostructure comprising the reduced symmetry material and a full symmetry material.

Example 15 includes the subject matter of any one of Examples 10-14, wherein the ME material layer comprises at least one of Bismuth, Iron, Oxygen, Lanthanum, Chromium, and Boron.

Example 16 includes the subject matter of any one of Examples 10-13, wherein the first FM material layer or second FM material layer comprises at least one of Cobalt, Iron, and Nickel.

Example 17 is an integrated circuit device comprising a plurality of deterministic logic devices, at least one deterministic logic device according to one of Examples 10-16.

Example 18 is an integrated circuit device assembly comprising a circuit board and the integrated circuit device of Example 9 and/or 17.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A probabilistic logic device comprising:
a spin orbit (SO) layer comprising a reduced symmetry material;
an insulating layer on the SO layer;
a ferromagnetic (FM) material layer on the insulating layer; and
a conductive electrode on the FM material layer.

2. The logic device of claim 1, wherein the reduced symmetry material comprises a two-dimensional (2D) transition metal dichalcogenide (TMD) material.

3. The logic device of claim 2, wherein the 2D TMD material comprises at least one of Niobium, Selenium, Molybdenum, and Tellurium.

4. The logic device of claim 1, wherein the SO layer defines a Hall cross structure, and the insulating layer and FM layer are formed in a middle portion of the Hall cross structure.

5. The logic device of claim 1, wherein the SO layer comprises a heterostructure comprising a first reduced symmetry material and a second reduced symmetry material.

6. The logic device of claim 1, wherein the SO layer comprises a heterostructure comprising the reduced symmetry material and a full symmetry material.

7. The logic device of claim 1, wherein the insulating layer comprises at least one of Magnesium, Aluminum, and Oxygen.

8. The logic device of claim 1, wherein the FM material layer comprises at least one of Cobalt, Iron, and Nickel.

9. An integrated circuit device comprising:
a plurality of probabilistic logic devices, at least one probabilistic logic device comprising:
a spin orbit (SO) layer comprising a two-dimensional (2D) transition metal dichalcogenide (TMD) material;
an insulating layer on the SO layer;
a ferromagnetic (FM) material layer on the insulating layer; and
a conductive electrode on the FM material layer.

10. The integrated circuit device of claim 9, wherein the 2D TMD material comprises at least one of Niobium, Selenium, Molybdenum, and Tellurium.

11. The integrated circuit device of claim 9, wherein the SO layer comprises a heterostructure comprising the 2D TMD material and another material.

12. The integrated circuit device of claim 9, wherein the SO layer defines a Hall cross structure, and the insulating layer and FM layer are formed in a middle portion of the Hall cross structure.

13. An integrated circuit device assembly comprising a circuit board and the integrated circuit device of claim 9.

14. A deterministic logic device comprising:
a magnetoelectric (ME) region comprising:
an ME material layer; and
a first ferromagnetic (FM) material layer on the ME material layer;
a spin orbit (SO) region comprising:
a spin orbital coupling layer comprising a reduced symmetry material;
a spin coherent layer on the spin orbital coupling layer;
a second FM material layer on the spin coherent layer;
wherein the ME region and the SO region are magnetically coupled via the first FM material and the second FM material.

15. The logic device of claim 14, wherein the reduced symmetry material comprises a two-dimensional (2D) transition metal dichalcogenide (TMD) material.

16. The logic device of claim 15, wherein the 2D TMD material comprises at least one of Niobium, Selenium, Molybdenum, and Tellurium.

17. The logic device of claim 14, wherein the spin orbital coupling layer comprises a heterostructure comprising a first reduced symmetry material and a second reduced symmetry material.

18. The logic device of claim 14, wherein the spin orbital coupling layer comprises a heterostructure comprising the reduced symmetry material and a full symmetry material.

19. The logic device of claim 14, wherein the ME material layer comprises at least one of Bismuth, Iron, Oxygen, Lanthanum, Chromium, and Boron.

20. The logic device of claim 14, wherein the first FM material layer or second FM material layer comprises at least one of Cobalt, Iron, and Nickel.
